(19) United States
(12) Patent Application Publication
(10) Pub. No.: US 2018/0061492 A1
(43) Pub. Date: Mar. 1, 2018

(54) WRITE BANDWIDTH ENHANCEMENT SCHEME IN PHASE CHANGE MEMORY

(71) Applicant: HGST Netherlands B.V., Amsterdam (NL)

(72) Inventors: Won Ho Choi, San Jose, CA (US); Jay Kumar, Saratoga, CA (US); Zvonimir Z. Bandic, San Jose, CA (US)

(21) Appl. No.: 15/247,158

(22) Filed: Aug. 25, 2016

(51) Int. Cl. G11C 13/00

(52) U.S. Cl. CPC G11C 13/0069; G11C 13/0023; G11C 13/0004

(57) ABSTRACT

In an aspect of the disclosure, a method and an apparatus are provided. The apparatus may be a phase change memory (PCM). The PCM including, first and second phase change memory cells. The PCM including a bitline coupled to the first and the second phase change memory cells. The PCM including a memory controller configured to simultaneously write to the first and the second phase change memory cells by applying designated pulse waveforms to the bitline and wordlines.

### BACKGROUND

### Field

The present disclosure relates generally to memory circuitry, and more particularly, to writing phase change memory.

### Background

Computer and network systems such as personal computers, workstations, server systems, and cloud storage systems, typically include data storage systems for storing and retrieving data. These data storage systems can include data storage devices, such as hard disk drives, solid-state storage devices, tape storage devices, and other mass storage devices.

Phase change memory can be employed in a computing system or storage system to store data. For example, a motherboard or other circuit board of a computing or a Solid-State-Drive (SSD) can employ one or more phase change memory to store data related to the operation of the computing or storage system.

A phase change memory cell is a device, which uses a chalcogenide material as a memory element. A memory element is the element that actually stores information. Thus, a phase change memory cell stores information on a memory element by changing the phase of the element by changing the phase of the element between amorphous and crystalline phases. A phase change memory cell can be changed from a crystalline state to an amorphous state, and vice versa, to store 1s and 0s associated with bits of data. Generally, the amorphous phase is associated with what is called a reset state and the crystalline state is associated with what is called a set state. In the write operation, a phase change memory cell may be transitioned through the application of bias voltages with different pulse widths and resulting currents to transition from amorphous to crystalline states or crystalline to amorphous states. In general, in these transitions, it is desirable to only change the phase of the cells you want to change and not the cells that you do not want to change. Typically, the transition from amorphous to crystalline states (so called reset-to-set transition) requires a longer pulse width period than the amorphous state for cooling down of the cell.

Phase change memories are arranged in what is called a cross-point memory where address lines are arranged in a grid. These address lines, normally called the bitline and word line, cross each other and memory elements span between the word lines and bitlines. In general, a select device (so called selector) is added to each memory cell to select a memory element. That is, a memory cell may include a series connected select device and memory element. One or multiple selected cells may be accessed by providing a select voltage on the appropriate bitlines and/or wordlines. Also phase change memories may use a deselect voltage to be driven on the inactive wordlines and/or bitlines to achieve proper biasing during a memory access.

### SUMMARY

In an aspect of the disclosure, a phase change memory is provided. The phase change memory includes first and second phase change memory cells in a memory cell array. The phase change memory also includes a bitline coupled to the first and the second phase change memory cells. Additionally, the phase change memory includes a bitline driver configured to apply a pulse to the bitline to write to the first and the second phase change memory cells during a single write pulse period.

In an aspect of the disclosure, a phase change memory is provided. The phase change memory includes first and second phase change memory cells. Additionally, the phase change memory includes a bitline coupled to the first and the second phase change memory cells. The phase change memory also includes bitline control circuitry configured to apply a pulse to the bitline to write to the first and the second phase change memory cells during a single pulse period.

In an aspect of the disclosure, a phase change memory is provided. The phase change memory includes first and second phase change memory cells. The phase change memory also includes bitline control circuitry. Additionally, the phase change memory includes a first wordline coupled to the first phase change memory cell. The phase change memory also includes a second wordline coupled to the second phase change memory cell. Additionally, the phase change memory also includes wordline control circuitry configured to simultaneously apply a first pulse to the first wordline to write to the first phase change memory cell and a second pulse to the second wordline to write to the second phase change memory cell, when bits to be written to the first and the second phase change memory cells are the same.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms, and its several details are capable of modification in various other respects. Accordingly, the drawings and detailed description are to be regarded as illustrative in nature and not as restrictive

### BRIEF DESCRIPTION OF THE DRAWINGS

FIG. 1 is a circuit diagram illustrating an example of a phase change memory cell with a selector (PCMS);

FIG. 2 is a conceptual block diagram illustrating an example of a phase change memory cell;

FIG. 3 is a graph illustrating temperature profile curves for phase changes in an example of a phase change memory cell;

FIG. 4 is a simplified circuit diagram illustrating an example of a phase change memory;

FIG. 5 is a detailed circuit diagram illustrating an example of the phase change memory of FIG. 4;

FIG. 6 is a circuit diagram illustrating an example of single bit write in the phase change memory;

FIG. 7 is a set of timing diagrams illustrating waveforms for two cases (reset, set) of the single bit write of FIG. 6;

FIG. 8 is a circuit diagram illustrating an example of parallel (or partially parallel) two bit write; and

FIG. 9 is a set of timing diagrams illustrating waveforms for three cases (reset-reset, set-set, reset-set) of the parallel (or partially parallel) two bit write of FIG. 8.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts. Acronyms and other descriptive terminology may be used merely for convenience and clarity and are not intended to limit any concept disclosed herein.

Various memories presented throughout this disclosure may be implemented as or in a stand-alone memory. Such aspects may also be included in any integrated circuit (IC) or system, or any portion of an integrated circuit or system (e.g., modules, components, circuits, or the like residing in an integrated circuit or part of an integrated circuit), or any intermediate product where an integrated circuit or system is combined with other integrated circuits or systems (e.g., a video card, a motherboard, etc.) or any end product (e.g., mobile phone, personal digital assistant (PDA), desktop computer, laptop computer, palm-sized computer, tablet computer, workstation, game console, media player, computer based simulators, wireless communication attachments for laptops, or the like).

The word “example” used throughout this disclosure means “serving as an example, instance, or illustration,” and should not necessarily be construed as preferred or advantageous over other examples presented in this disclosure.

The terms “connected,” “coupled,” or any variant thereof, mean any connection or coupling, either direct or indirect, between two or more elements, and may encompass the presence of one or more intermediate elements between two elements that are “connected” or “coupled” together.

Any reference to an element herein using a designation such as “first,” “second,” and so forth does not limit the quantity or order of those elements. Rather, these designations are used herein as a convenient method of distinguishing between two or more elements or instances of an element. Thus, a reference to first and second elements does not mean that only two elements can be employed, or that the first element must precede the second element. As used herein, references to the plural include the singular, and references to the singular include the plural.

Various aspects of a memory will now be presented in the context of a PCM. While these aspects may be well suited for these applications, those skilled in the art will realize that such aspects may be extended to other applications. Accordingly, any reference to a PCM is intended only to illustrate various aspects, with the understanding that such aspects may have a wide range of applications.

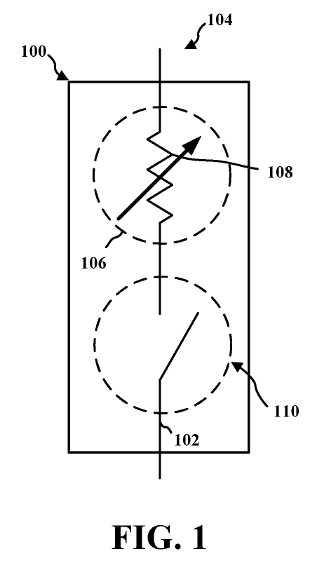

FIG. 1 is circuit diagram illustrating an example of a phase change memory cell with a selector (PCMS) 100. The PCMS cell 100 includes a bitline 102 and a wordline 104 connected to a selector 110. The selector 110 acts as a switch to provide current flow to a storage element 106 that may be used to write to the storage element 106. The storage element 106 includes phase change memory material 108. The phase change memory material 108 is modeled as a variable resistor. Additionally, the storage element 106 includes two inputs. As illustrated in FIG. 1, one input of the storage element 106 is connected to the selector 110. The other input of the storage element 106 is connected to wordline 104.

The PCMS cell 100 may store information in the storage element 106 based on the state of the phase change memory material 108. The resistance of the phase change memory material 108 may vary depending on the state of the phase change memory material 108.

The PCMS cell 100 may be used to write data to the storage element 106 when the bitline 102 and the wordline 104 are active. For example, when the bitline 102 and the wordline 104 are active, the selector 110 will be on, and current may flow from wordline 104 through the storage element 106 and the selector 110 to the bitline 102. Different pulse waveforms may be inputs on the wordline and bitline to control heating of the phase change memory material 108. The state of the phase change memory material 108 may be set or reset depending on the heating of the phase change memory material 108. Generally, the phase change memory material 108 may be programmed to one of two (or more) states. Typically, two states, set or rest, are used. The set state may be used to represent storage of a logic “0” and the reset state may be used to represent a logic “1” value. In an example, the set state may be in a crystalline state. In the crystalline state, the phase change memory material 108 may have a relatively low resistivity, e.g., the phase change memory material 108 may be modeled as a resistor with a relatively low resistance. Conversely, the reset state may be an amorphous state. In the amorphous state, the phase change memory material 108 may have a relatively high resistivity, e.g., the phase change memory material 108 may be modeled as a resistor with a relatively high resistance. The heating may be controlled by selecting different pulse waveforms to be inputs on the wordline 104 and bitline 102.

The resistance of the phase change memory material 108 varies with the state of the phase change material. Accordingly, the phase change memory cell 100 may be read based on the resistance of the phase change memory material 108.

The PCMS cell 100 illustrated in FIG. 1, may use a low voltage (e.g., Vss) on the bitline 102 as an active voltage to cause current to flow (e.g., when the wordline 104 is active).

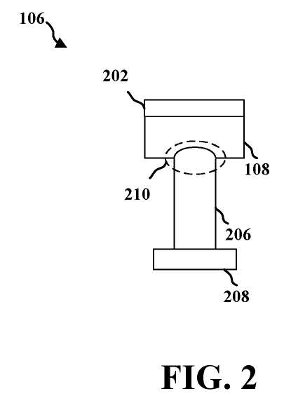

FIG. 2 is a conceptual block diagram illustrating the example storage element 106 of the PCMS cell illustrated in FIG. 1. The example storage element 106 includes a top electrode 202 coupled to the phase change memory material 108. A heater resistor 206 may be in contact with the phase change memory material 108. In the illustrated example of FIG. 2, the heater resistor 206 may be opposite the top electrode 202 with the PCM material 108 in between. The storage element 106 also includes a bottom electrode 208. A voltage may be applied between the top electrode 202 and the bottom electrode 208. When a voltage is applied between the top electrode 202 and the bottom electrode 208, the heater resistor 206 may heat the phase change memory material 108 at the active area 210. The heater resistor 206 should not be confused with the variable resistor that is used to model the phase change memory material 108 in FIG. 1. Rather, the heater resistor 206 may be used to generate heat that may impact the state of the phase change memory material 108. Accordingly, the heater resistor 206 may be used to change the resistance of the phase change memory material 108. Different pulse waveforms may be applied to the top electrode and bottom electrode to store information by changing the state or phase of the phase change memory material 108.

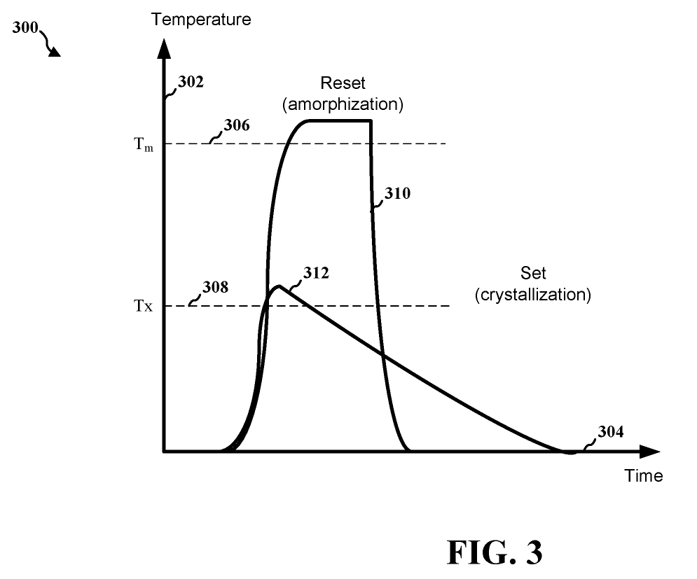

FIG. 3 is a graph 300 illustrating example temperature profile curves for phase changes in a storage element such as the example storage element 106 of the PCMS cell 100 illustrated in FIG. 1. (The example storage element 106 is further detailed in FIG. 2, as discussed above.) In the graph 300, the X-axis 304 is time, and the Y-axis 302 is temperature. The melting temperature for amorphization, Tm, 306 may generally be a higher temperature than the temperature for crystallization, Tx, 308. The reset temperature profile 310 (amorphization) may generally be shorter than the set temperature profile 312 (crystallization). Accordingly, the reset temperature profile 310 may be a hotter, but shorter temperature profile, as illustrated in FIG. 3 and the set temperature profile 312 may be a cooler, but longer temperature profile, as also illustrated in FIG. 3.

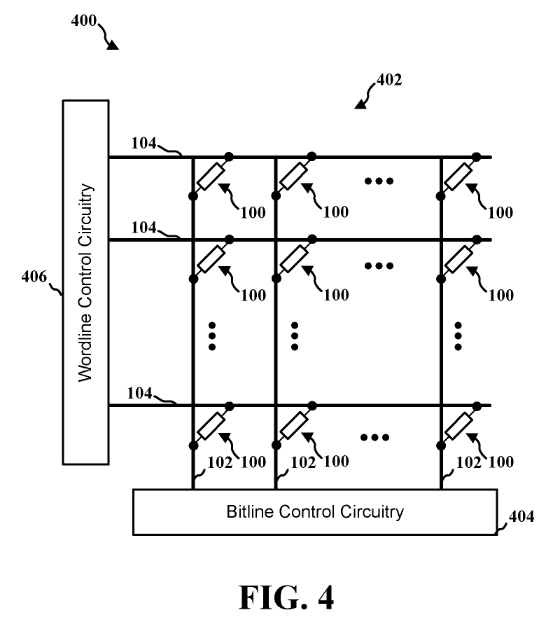

FIG. 4 is a simplified circuit diagram illustrating an example PCM memory 400. The PCM memory 400 includes a PCM array 402, bitline control circuitry 404, and wordline control circuitry 406. The PCM array 402 includes a plurality of PCMS cells 100 which may be similar to the PCMS cell 100 illustrated in FIG. 1. The plurality of PCMS cells 100 are each connected to a bitline 102 and a wordline 104. As illustrated in FIG. 4, a number of PCMS cells 100 may be connected to a single bitline 102. Similarly, a number of PCMS cells 100 may be connected to a single wordline 104. Accordingly, the PCMS cells 100 may be arranged in a matrix of bitlines 102 and wordlines 104.

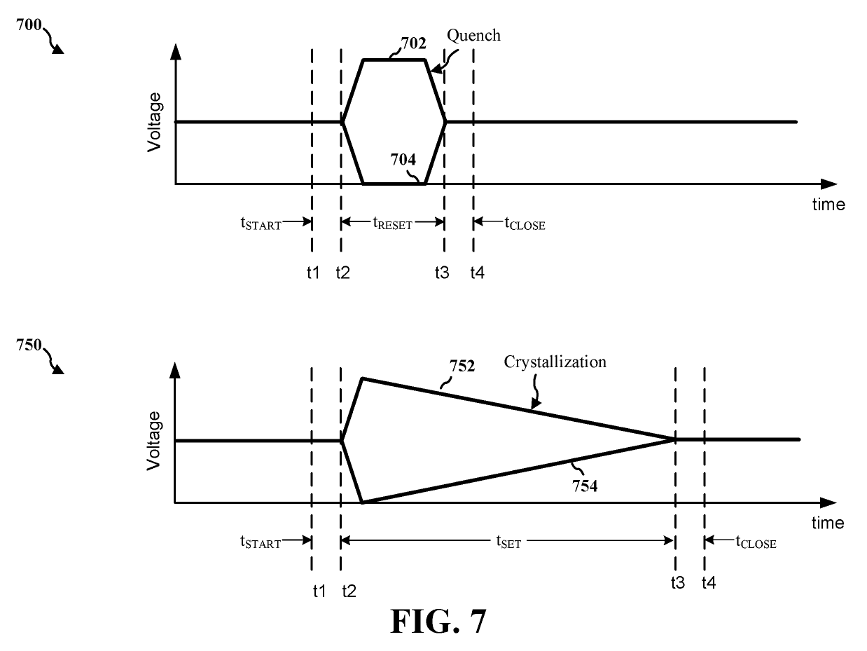

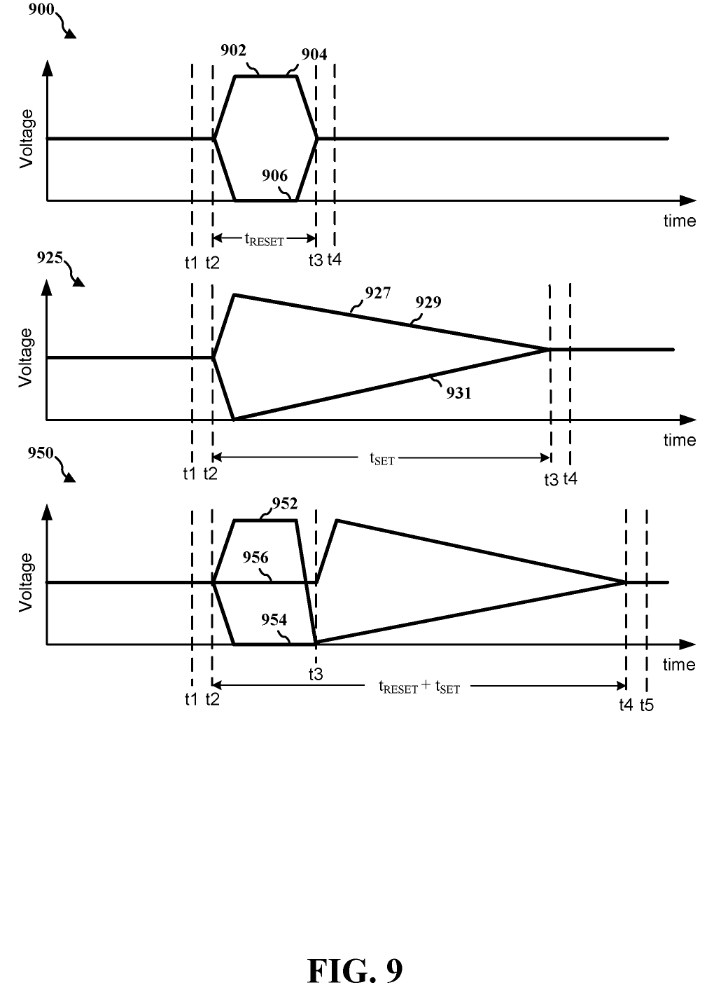

The wordline control circuitry 406 may be used to select and drive the wordlines 104. For example, one of the wordlines 104 may be asserted to enable all PCMS cells 100 attached to the particular wordline 104 to be written. The bitline control circuitry 404 may be used to select and drive the bitlines 102. For example, one of the bitlines 102 may be asserted so that a PCMS cell 100 that is enabled by the wordline and attached to the particular bitline 102 may be written. Accordingly, if a single bitline 102 in the PCM array 402 is asserted and a single wordline 104 in the PCM array 402 is asserted, a PCMS cell 100 connected to the driven bitline 102 and the driven wordline 104 may be written. The specific data written to the particular PCMS cell 100 may depend on the pulse waveforms applied to the particular bitline 102 and the particular wordline 104, as will be discussed in greater detail with respect to FIGS. 7 and 9.

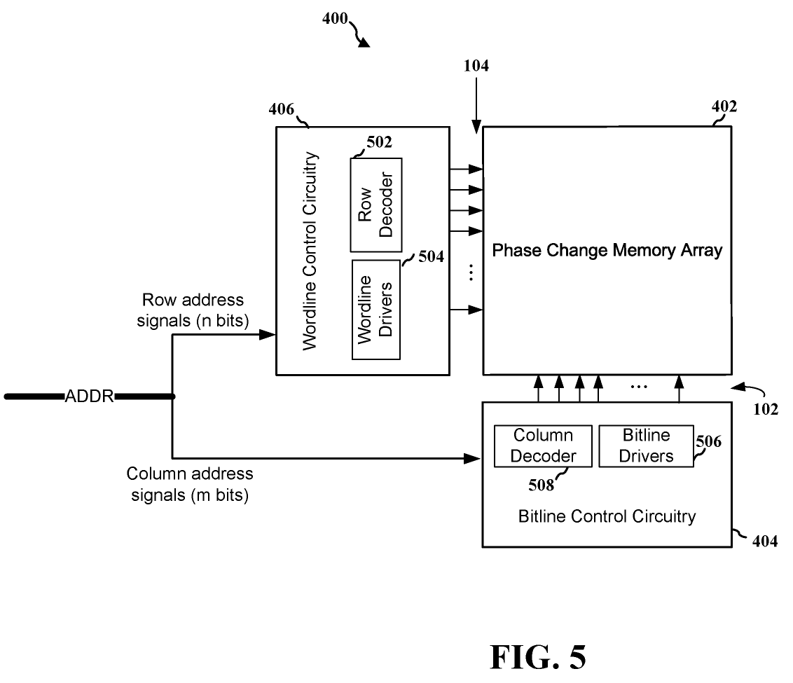

FIG. 5 is a circuit diagram illustrating additional details of the example PCM memory of FIG. 4. The PCM memory 400 includes the PCM array 402, a bitline control circuitry 404, and a wordline control circuitry 406. As discussed above, the PCM array 402 includes a plurality of PCMS cells 100 which may be similar to the PCMS cell 100 illustrated in FIG. 1. The plurality of PCMS cells 100 are each connected to a bitline 102 and a wordline 104.

The wordline control circuitry 406 may be used to select and drive the wordlines 104. As illustrated in FIG. 5, the wordline control circuitry 406 may include a row decoder 502 and wordline drivers 504. The row decoder 502 may select the wordline 104 and the wordline drivers 504 may generate a pulse to apply to the selected wordline and drive the wordline. The wordlines 104 may be selected based a subset of the address comprising, in this example, (n) address bits. The (n) address bits are decoded by the row decoder 502 into generate 2ⁿ signals, which are provided to the wordline drivers 504. The wordline drivers 504 may generate pulse waveforms used to enable the PCMS cells 100 in the PCM array 402. Example waveforms that may be used to perform writes to the PCMS cells 100 are illustrated in FIGS. 7 and 9.

The bitline control circuitry 404 may be used to select and drive the bitlines 102. As illustrated in FIG. 5, the bitline control circuitry 404 may include bitline drivers 506, a column decoder 508. The column decoder 508 may select the bitline 102 and the bitline drivers 506 may generate a pulse to apply to the selected bitline and drive the bitline. The column decoder 508 is used to decode a subset of the address comprising, in this example, (m) address bits. The (m) address bits may be decoded by the column decoder 510 into 2^{m} signals which are used to drive the select input to the bitline drivers 506. The bitline drivers 506 may generate pulse waveforms used to perform writes to the PCMS cells 100 in the PCM array 402. Example waveforms that may be used to perform writes to the PCMS cells 100 are illustrated in FIGS. 7 and 9.

As illustrated in FIG. 5, the write data may be routed to the bitline control circuitry 404. The write date includes a number of bits to be written to the PCM memory 400. As to be explained in greater detail later, the bitline drivers 506 may be used to shape the pulse applied to the selected bitline based on the state of a write bit to be written to the PCM memory 400. The write data may also be routed to the wordline drivers 504 in the wordline control circuitry 406. As will also be explained in greater detail later, the pulses applied to the wordlines may also be a function of the state of the bits to be written to the PCM memory 400.

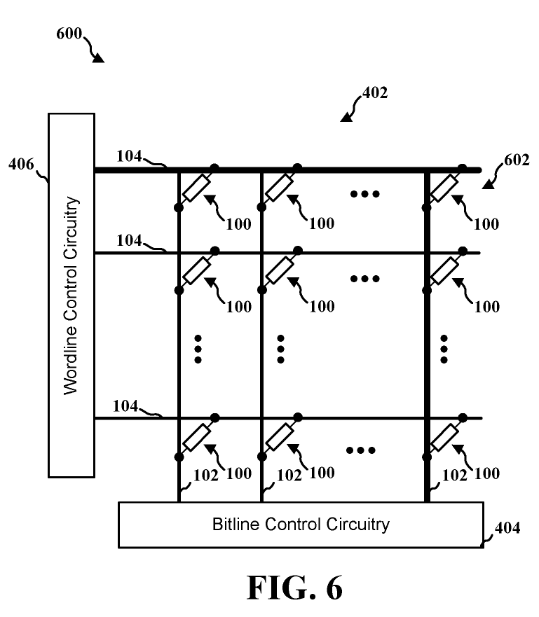

FIG. 6 is a circuit diagram 600 illustrating an example single bit write. The circuit diagram 600 of FIG. 6 is generally similar to the circuit diagram of FIG. 4 illustrating the example PCM memory 400. In the circuit diagram 600, the wordline control circuitry 406 asserts a single wordline 104. In FIG. 6, the asserted wordline 104 is indicated by an increased line thickness of a single wordline 104 relative to the other wordlines 104. Additionally, in the circuit diagram 600, the bitline control circuitry 404 asserts a single bitline 102. In FIG. 6, the asserted bitline 102 is also indicated by an increased line thickness of the single bitline 102 relative to the other bitlines 102. Accordingly, in the example of FIG. 6, the PCMS cell 100 at location 602 is the PCMS cell 100 being written to.

FIG. 7 is a set of timing diagrams 700, 750 illustrating waveforms for two cases (reset, set) of the single bit write of FIG. 6. The waveforms for the single bit write of FIG. 6 may be generated by the PCM memory 400 illustrated in FIGS. 4-5. For example, the PCM memory 400 may be addressed using the address lines. The address lines may be made up of a number of bits, (n+m), where n may represent the n least significant bits, and m may represent the m most significant bits. The n least significant bits may be input into the wordline control circuitry 406, and more particularly, the row decoder 502. The row decoder 502 may then decode the n least significant bits into 2ⁿ wordlines with one asserted wordline. The row decoder 502 may then drive the wordline drivers 504, which may generate the pulse waveforms illustrated in the timing diagram is 700, 750 to drive the asserted wordline. The particular pulse waveform generated may be based on the bit to be written by the wordline drivers 504.

The m most significant bits may be input into the bitline control circuitry 404, and more particularly, the column decoder 508. The column decoder 508 may then decode the m most significant bits to determine which bitline should be active to perform a desired write. The column decoder 508 may then drive the bitline drivers 506, which may generate the pulse waveforms illustrated in the timing diagram is 700, 750 to drive the bitlines. More specifically, the column decoder 510 decodes the m-bit input into 2^{m} signals. The 2^{m} signals may then be used to drive the select input to the column decoder 508 to select the bitline 102. The bitline drivers 506 generates a pulse having a waveform (e.g., as illustrated in FIGS. 7 and 9) that is a function of the bit to be written to memory, e.g., storage elements 106 in PCMS cells 100 in the PCM array 402. The pulse is then applied by the bitline drivers 506 onto the selected bitline 102.

The first timing diagram 700 illustrates a “reset” waveform. In the described examples, the state of the phase change material when reset may be used to represent a logic “1” value. In other examples, the state of the phase change material when reset may be used to represent a logic “1” value. The wordline 104 may vary between Vwrite and a baseline, and the bitline may vary between Vss and a baseline, with the baseline being, for example, (Vwrite−Vss)/2. The wordline and bitline drivers each output pulses. The wordline driver may output a pulse that has a ((Vwrite−Vss)/2) voltage baseline, a sloped leading edge, a Vwrite peak, and a sloped trailing edge. The bitline driver outputs a pulse that has a ((Vwrite−Vss)/2) baseline and a negative peak at Vss. The voltage differential during the peaks is Vwrite−Vss, which is the voltage from wordline 104 to bitline 102 in the selected PCMS cell 100. As illustrated in the first timing diagram 700, the voltage on the bitline 704 and the voltage on the wordline 702 may be equal prior to the time t1. With the wordline and bitline at the same voltage, the selector (e.g., selector 110) is off

The write may begin at the time, t2, after the set-up time has been met. The set-up time is the time between t1 and t2. The set-up time is the time required for both the wordline and bitline to be at the baseline voltage before beginning a new write after a previous write. At a time, t2, the voltage on the bitline 704 may be driven low, e.g., Vss, and the voltage on the wordline 702 may be driven high, e.g., Vwrite. With the wordline 104 high and the bitline 102 low, the selector 110 is driven into an “on” state. Accordingly, current may flow through the phase change material.

The heating caused by the current flow due to the voltage waveforms illustrated in the first timing diagram 700 may be a heating and fast quenching. For example, the reset process may end at a time, t3, at which point the bitline and wordline return to the baseline voltage for a minimum hold time for a subsequent write, t3 to t4.

The second timing diagram 750 illustrates a “set” waveform. In the described examples, the set waveform may write a logic “0” to the phase change memory material for that particular write. As discussed above, the wordline and bitline drivers each output pulses. The wordline driver may output a pulse having a ((Vwrite−Vss)/2) voltage baseline, a sloped leading edge, a Vwrite peak, and a sloped long trailing edge. The bitline driver outputs a pulse that has a ((Vwrite−Vss)/2) baseline and a negative peak at Vss. The voltage differential during the peaks is Vwrite−Vss, which is the voltage from wordline 104 to bitline 102 in the selected PCMS cell 100. As illustrated in the second timing diagram 750, the voltage on the bitline 754 and the voltage on the wordline 752 may be equal prior to the time t1. With the wordline and bitline at the same voltage, the selector 110 is off.

The write may begin at the time, t2, after the set-up time has been met. The set-up time is the time between t1 and t2. The set-up time is the time required for both the wordline and bitline to be at the baseline voltage before beginning a new write after a previous write. At a time, t2, the voltage on the bitline 754 may be driven low and the voltage on the wordline 702 may be driven high. With the wordline high and the bitline low, the selector is driven into an “on” state. Accordingly, current may flow through a selector and a storage element, such as the selector 110 and the storage element 106 illustrated in FIG. 1. The long trailing edge of the pulse has a smaller slope, e.g., as compared to the slope of the short trailing edge of the pulse in timing diagram 700. Accordingly, the heating may initially be the same or similar to the heating illustrated in the first timing diagram 700, followed by a slow fall off in heating. Reducing the heat applied to the phase change material at a slower rate may result in crystallization, as opposed to amorphization with a quicker reduction in heat.

The difference between the two waveforms 752, 754 is the voltage difference between wordline and bitline for the particular PCMS cell 100. At the same time, the voltage across the selector is changed by the difference between wordline and the bitline. The set process may end at a time, t3, after crystallization has occurred, at which point the bitline and wordline return to the baseline voltage for a minimum hold time for a subsequent write.

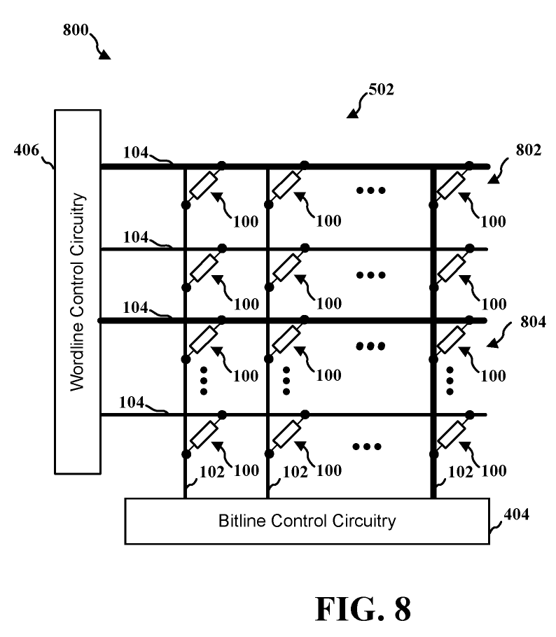

FIG. 8 is a circuit diagram illustrating an example of parallel (or partially parallel) two bit write. The circuit diagram 800 of FIG. 8 is generally similar to the circuit diagram of FIG. 4 illustrating the example PCM memory 400. In the circuit diagram 800, the wordline control circuitry 406 asserts two wordlines 104. In FIG. 8, the asserted wordlines 104 are indicated by an increased line thickness of the pair of wordlines 104 relative to the other wordlines 104. Additionally, in the circuit diagram 800, the bitline control circuitry 404 asserts a single bitline 102. In FIG. 8, the asserted bitline 102 is also indicated by an increased line thickness of the single bitline 102 relative to the other bitlines 102. Accordingly, in the example of FIG. 8, the PCMS cells 100 at location 802, 804 are being written.

FIG. 9 is a set of timing diagrams 900, 925, 950 illustrating waveforms for three cases (reset-reset, set-set, reset-set) of the parallel (or partially parallel) two bit write of FIG. 8. Referring to FIGS. 5 and 9, the bitline control circuitry 404 generates a single pulse that is able to write to two PCMS cells during the single pulse period. This is accomplished by the wordline control circuitry 406 enabling two PCMS cells connected to the bitline driven by the bitline control circuitry 404. In this example, the wordline control circuitry 406 receives two write addresses, either in parallel on a wide address bus ADDR or in serial. In the case where the two write addresses are received by the wordline control circuitry 406 in serial, the addresses may be latched in the row decoder 502 input circuitry or elsewhere in the wordline control circuitry 406. Each address may be made up of a number of bits, (n+m), where n may represent the n least significant bits, and m may represent the m most significant bits. The n least significant bits for a write may be input into the row decoder 502. The row decoder 502 may then decode the n least significant bits to determine which wordline should be asserted in response to the write address. As will be described in greater detail later, the wordline drivers 504 apply the appropriate waveforms to the asserted wordlines based on the first write bit to be written to the corresponding PCMS cell 100 and the second write bit to be written to the other PCMS cell 100. The write bits are received by the wordline control circuitry 406.

The m most significant bits may be input into the bitline control circuitry 404, and more particularly, the column decoder 508. The column decoder 508 may then decode the m most significant bits to determine which bitline should be asserted to perform a desired write. More specifically, as discussed above, the column decoder 508 decodes the m-bit input into 2^{m} signals. The 2^{m} signals may then be used to drive the select input to the column drivers 506 to select the bitline 102. As will be described in greater detail later, the bitline drivers 506 generate corresponding pulses having the appropriate waveform based on both write bits to be written to the two different PCMS cells. The write bits are received by the bitline control circuitry 404. The pulses are then applied by the bitline drivers 506 onto the selected bitline 102.

In the described example, the row decoder is configured to assert two wordlines during a single pulse period of the bitline. This may be implemented in various ways. By way of example, the row decoder 502 may include two decoder circuits, e.g., with one decoder circuit dedicated to the first (or upper) half of the 2ⁿ rows of the PCM array 402 and a second decoder dedicated to the second (or lower) half of the 2ⁿ rows of the PCM array 402. The PCM memory array 402 is sometimes referred to as a “tile.” Using this termination, the first decoder circuit is used to select a wordline from the upper tile and the second decoder circuit is used to select a wordline from the lower title. With this arrangement, the asserted wordlines will reside in different tiles. Preferably, the selected wordlines are at least a half-tile apart to for thermal isolation. As described herein, PCMS cells may be written using heat generated by current flow. In some cases, heating two PCMS cells that are too close together may lead to incorrect results due to heat from a first write impacting a second write and/or heat from the second write impacting the first write. The remote apparatus that provides the address to the row decoder will need to be configured to support this configuration. Various other decoders may be implemented by those skilled in the art which address two wordlines, either simultaneously or sequentially, that are at least a half-tile apart or have no spacing requirement.

The first timing diagram 900 illustrates three waveforms 902, 904, 906, to reset two different PCMS cells having a common bitline. The waveforms 902, 904 are applied by the wordline driver to two separate wordlines simultaneously. The bitline 906 waveform may be applied by the bitline driver to the bitline.

The first timing diagram 900 illustrates a reset on a first PCMS cell and a reset on a second PCMS cell. The wordline drivers and bitline driver output pulses. Each wordline driver may output a pulse on each of two wordlines that has a ((Vwrite−Vss)/2) voltage baseline, a sloped leading edge, a Vwrite peak, and a sloped trailing edge. The shape of these waveforms may be determined by the wordline drivers 504 based on write bits that reset two PCMS cells connected to a common bitline. The bitline driver outputs a pulse onto the bitline that has a ((Vwrite−Vss)/2) baseline, a sloped leading edge, a negative peak at Vss, and a sloped trailing edge. The shape of the waveform applied to the bitline may be determined by the bitline drivers 506 based on write bits that reset the two PCMS cells.

As illustrated in the first timing diagram 900, the voltage on the bitline 906 and the voltage on the wordlines 902, 904 may be equal prior to the write, e.g., at baseline ((Vwrite−Vss)/2). With both wordlines and the bitline at the same voltage, the voltage across each PCMS cell to be written is 0V, thereby keeping the selectors off

After any required set-up time, e.g., (from t1 to t2), the voltage on the bitline 906 may be driven low, e.g., Vss, and the voltage on the wordlines 902, 904 may be driven high, e.g., Vwrite. As a result, the voltage across each PCMS cell to be written is (Vwrite−Vss), thereby forcing the selectors on, causing current to flow through the two selectors. At t3, the bitline 906 and the voltage on the wordlines 902, 904 are driven back to the baseline voltage with a waveform having a steep sloped trailing edge. The voltage across each of PCMS cells is quickly driven to 0V, thereby forcing the selectors off. The heating caused by the current flow due to the pulse waveforms illustrated in the first timing diagram 900 may result in heating and fast quenching, e.g., during the time, t_{RESET}. The heating and fast quenching result in the phase change memory material in each cell being forced into an amorphous state, which in this example is a reset state.

The time from t3 to t4 may indicate a hold time for a subsequent write.

The second timing diagram 925 illustrates writing a set on a first cell and a set on a second cell. The wordline drivers and bitline driver each output pulses. Each wordline driver may output a pulse having a ((Vwrite−Vss)/2) voltage baseline, a sloped leading edge, a Vwrite peak, and a sloped long trailing edge. The shape of these pulse waveforms may be determined by the wordline drivers 504 based on write bits that set two PCMS cells connected to a common bitline. The bitline driver outputs a pulse onto the bitline that has a ((Vwrite−Vss)/2) baseline, a sloped leading edge, a negative peak at Vss, and a sloped long trailing edge. The shape of the pulse waveform applied to the bitline may be determined by the bitline drivers 506 based on write bits that set the two PCMS cells. As compared to the first timing diagram 900, the slope of the trailing edge of the waveform applied to the bitline and to each of the wordlines is more gradual to set the two PCMS cells.

As illustrated in the second timing diagram 925, the voltage on the bitline 931 and the voltage on the wordlines 927, 929 may be equal prior to the write, e.g., at a baseline ((Vwrite−Vss)/2). With the wordlines and bitline at the same voltage, the voltage across each PCMS cell to be written is 0V, thereby keeping the selectors off

After any required set-up time, e.g., (from t1 to t2), the voltage on the bitline 931 may be driven low, e.g., Vss, and the voltage on the wordlines waveforms 927, 929 may be driven high, e.g., Vwrite. As a result, the voltage across each PCMS cell to be written is (Vwrite−Vss), thereby forcing the selectors on, causing current flow through each selectors. At t3, the bitline 931 and the voltage on the wordlines 927, 929 are driven back to the baseline voltage with a waveform having a gradually sloped trailing edge, as opposed to the steep trailing edge in the first timing diagram 900. The voltage across each of the PCMS cells is slowly driven back to 0V as the bitline 931 gradually increase from Vss to the baseline voltage and the wordlines 927, 927 gradually decreases from Vwrite to the baseline voltage. At the same time, the voltage across each of the PCMS gradually decreases resulting in longer cooling for the phase change memory material in both the PCMS cells, thereby forcing the phase change material into a crystalline state, as opposed to amorphous state with a quicker reduction in heat. The parallel set process end after crystallization has occurred, at which point, the bitline and wordline return to the baseline voltage for a minimum hold time for a subsequent write.

The time from t3 to t4 may indicate a hold time for a subsequent write.

The third timing diagram 950 illustrates three waveforms 952, 954, 956 to reset a first PCMS cell and set a second PCMS cell. The bitline 954 waveform may be applied by the bitline driver to the bitline. The waveforms 952, 954 may be applied by the wordline drivers to two separate wordlines during the single pulse period for the bitline 954.

As illustrated in the timing diagram 950, the voltage on the bitline 954 and the voltage on the wordlines 952, 956 may be equal prior to the write, e.g., at baseline ((Vwrite-Vss)/2). With the wordline and bitline at the same voltage, the voltage across each PCMS cell to be written is 0V, thereby keeping the selectors off

After any required set-up time, e.g., (from t1 to t2), the voltage on the bitline 954 may be driven low, e.g., Vss, and the voltage on the wordline 952 connected to the first PCMS cell may be driven high, e.g., Vwrite. As a result, the voltage across first PCMS cell is (Vwrite−Vss), thereby forcing the selector on, causing current to flow through the selector. At t3, the voltage on the wordlines 952 is driven to Vss with a waveform having a steep sloped trailing edge. With the bitline 954 at Vss and the wordline 956 at baseline ((Vwrite−Vss)/2), the voltage across the first PCMS cell is quickly driven to 0V, thereby forcing the selector off. The heating caused by the current flow due to the pulse waveforms illustrated in the third diagram 950 may result in heating and fast quenching for the first PCMS cell. The heating and fast quenching result in the phase change memory material in the first PCMS cell being forced into an amorphous state. The voltage on the wordline 952 and the bitline 954 increase gradually together from Vss to the baseline voltage at t4. During this period, the voltage across the first PCMS cell remains at 0V, thereby keeping the selector off

Between t2 and t3, the voltage on the wordline 956 remains at the baseline voltage. As a result, the voltage across the second PCMS cell is ((Vwrite−Vss)/2). It is still below the threshold voltage of the selector which is a general requirement of the selector in memory array, thereby keeping the selector off. At t3, the wordline 956 voltage is driven to high, e.g., Vwrite. As a result, the voltage across the second PCMS cell is (Vwrite−Vss), thereby driving the selector on, causing current to flow through the selector. The voltage on the wordline 956 is then driven back to the baseline voltage with a waveform having a gradually sloped long trailing edge, which is complimentary to the trailing edge of the bitline 954. The voltage across the second PCMS cell is slowly driven back to 0V as the bitline 954 gradually increase from Vss to the baseline voltage at t4 and the wordline 956 gradually decreases from Vwrite to the baseline voltage at t4. At the same time, the voltage across PCMS cell gradually decreases resulting in longer cooling for the phase change memory material in the second PCMS cell, thereby forcing the phase change material into a crystalline state. The set process may end after crystallization has occurred, at which point, the bitline 954 and wordline 956 return to the baseline voltage for a minimum hold time for a subsequent write.

The time from t4 to t5 may indicate a hold time for a subsequent write in the third timing diagram 950.

The various aspects of this disclosure are provided to enable one of ordinary skill in the art to practice the concepts disclosed herein. Various modifications to example aspects presented throughout this disclosure will be readily apparent to those skilled in the art, and the example aspects disclosed herein may be extended to other applications. Thus, the claims are not intended to be limited to the various aspects of this disclosure, but are to be accorded the full scope consistent with the language of the claims. All structural and functional equivalents to the various components of a PCM described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f), or the applicable analogous statute or rule of law, unless the element is expressly recited using the phrase “means for” or, in the case of a method claim, the element is recited using the phrase “step for.”

1. A phase change memory device, comprising:
first and second phase change memory cells;
a single bitline coupled to the first and the second phase change memory cells; and
bitline control circuitry configured to apply a pulse to the bitline to write to the first and the second phase change memory cells during a single pulse period.

2. The phase change memory device of claim 1, wherein the bitline control circuitry is further configured to write to the first and the second phase change memory cells simultaneously during the single pulse period when bits to be written to the first and the second phase change memory cells are the same.

3. The phase change memory device of claim 1, wherein the bitline control circuitry is further configured to write to the first and the second phase change memory cells sequentially during the single pulse period when bits to be written to the first and the second phase change memory cells are different.

4. The phase change memory device of claim 1, wherein the bitline control circuitry is configured to generate the pulse with a trailing edge having a slope dependent on bits to be written to the first and the second phase change memory cells.

5. The phase change memory device of claim 1, further comprising:
a first wordline coupled to the first phase change memory cell;
a second wordline coupled to the second phase change memory cell; and
wordline control circuitry configured to apply, during the single pulse period, a first pulse to the first wordline to write to the first phase change memory cell and a second pulse to the second wordline to write to the second phase change memory cell.

6. The phase change memory device of claim 5, wherein the wordline control circuitry are further configured to apply the first and the second pulses simultaneously during the single pulse period when bits to be written to the first and the second phase change memory cells are the same.

7. The phase change memory device of claim 5, wherein the wordline control circuitry are further configured to apply the first and the second pulses sequentially during the single pulse period when bits to be written to the first and the second phase change memory cells are different.

8. The phase change memory device of claim 5, wherein the wordline control circuitry are further configured to generate each of the first and the second pulses with a trailing edge having a slope dependent on bits to be written to the first and the second phase change memory cells.

9. A phase change memory device, comprising:
first and second phase change memory cells;
a single bitline coupled to the first and the second phase change memory cells; and
bitline control circuitry configured to simultaneously write to the first and the second phase change memory cells when bits to be written to the first and the second phase change memory cells are the same.

10. The phase change memory device of claim 9 wherein the bitline control circuitry is configured to apply a pulse to the single bitline to write to the first and the second phase change memory cells during a single pulse period.

11. The phase change memory device of claim 10 wherein the bitline control circuitry is further configured to write to the first and the second phase change memory cells sequentially during the single pulse period when the bits to be written to the first and the second phase change memory cells are different.

12. The phase change memory device of claim 10, wherein the bitline control circuitry is further configured to generate the pulse with a trailing edge having a slope dependent on bits to be written to the first and the second phase change memory cell.

13. The phase change memory device of claim 10, further comprising:
a first wordline coupled to the first phase change memory cell;
a second wordline coupled to the second phase change memory cell; and
wordline control circuitry configured to apply a first pulse to the first wordline to enable the bitline control circuitry to write to the first phase change memory cell and a second pulse to the second wordline to enable the bitline control circuitry to write to the second phase change memory cell.

14. The phase change memory device of claim 13, wherein the wordline control circuitry are further configured to apply the first and the second pulses simultaneously when bits to be written to the first and the second phase change memory cells are the same.

15. The phase change memory device of claim 13, wherein the wordline control circuitry are further configured to apply the first and the second pulses sequentially when bits to be written to the first and the second phase change memory cells are different.

16. The phase change memory device of claim 13, wherein the wordline control circuitry are further configured to generate each of the first and the second pulse with a trailing edge having a slope dependent on bits to be written to the first and the second phase change memory cells.

17. A phase change memory device, comprising:
first and second phase change memory cells;
bitline control circuitry;
a first wordline coupled to the first phase change memory cell;
a second wordline coupled to the second phase change memory cell, the first phase change memory cell and the second phase change memory cell coupled to a single bitline; and
wordline control circuitry configured to simultaneously apply a first pulse to the first wordline to write to the first phase change memory cell and a second pulse to the second wordline to write to the second phase change memory cell, when bits to be written to the first and the second phase change memory cells are the same.

18. The phase change memory device of claim 17, wherein the bitline control circuitry is configured to apply a pulse to the single bitline to write to the first and the second phase change memory cells during a single pulse period.

19. The phase change memory device of claim 18 wherein the wordline control circuitry are configured to sequentially apply the first pulse to the first wordline and the second pulse to the second wordline during the single pulse period when the bits to be written to the first and the second phase change memory cells are different.

20. The phase change memory device of claim 18, wherein the bitline control circuitry is further configured to generate the pulse with a trailing edge having a slope dependent on bits to be written to the first and the second phase change memory cells.

21. The phase change memory device of claim 17, wherein the wordline control circuitry are further configured to generate each of the first and the second pulse with a trailing edge having a slope dependent on bits to be written to the first and the second phase change memory cells.
